(19) United States
(12) Patent Application Publication
(10) Pub. No.: US 2006/0073417 A1
(43) Pub. Date: Apr. 6, 2006

(54) Photopolymer plate and method for imaging the surface of a photopolymer plate

(76) Inventor: Mark Hermesdorf, Woodstock, GA (US)

Correspondence Address: NEEDLE & ROSENBERG, P.C., SUITE 1000, 999 PEACHTREE STREET, ATLANTA, GA, 30309-3915, US

(21) Appl. No.: 11/112,853

(22) Filed: Apr. 22, 2005

Related U.S. Application Data
(60) Provisional application No. 60/564,861, filed on Apr. 23, 2004.
(60) Provisional application No. 60/655,213, filed on Feb. 22, 2005.

(51) Int. Cl. G03F 7/00

(52) U.S. Cl. 430/302

(57) ABSTRACT

A flexographic printing plate and a method for making a flexographic printing plate. According to one aspect, the method comprises the steps of providing a photopolymer substrate having a top surface pretreated with a non-gelatinous inkjet receptive coating; image-wise ink jetting an inkjet composition onto a portion of the pretreated surface of the photopolymer substrate to provide a photomask layer; exposing the photopolymer substrate to ultraviolet light to cure an unmasked portion of the photopolymer substrate; and processing the photopolymer substrate under conditions effective to render the cured unmasked portion of the photopolymer layer into a raised image surface suitable for use in a flexographic printing process.

### CROSS-REFERENCE TO RELATED APPLICATIONS

This application claims priority to U.S. Patent Application Ser. No. 60/564,861, filed Apr. 23, 2004, and to U.S. Patent Application Ser. No. 60/655,213, filed Feb. 22, 2005, the entire disclosures of which are hereby incorporated by reference in their entirety for all purposes.

### FIELD OF THE INVENTION

The present invention relates generally to the field of flexography and more particularly to a process for manufacturing a flexographic printing plate suitable for use in a flexographic printing process.

### BACKGROUND OF THE INVENTION

Flexography is a modified letterpress printing method that has become increasingly prevalent in the packaging industry for printing on a variety of materials. Flexography generally uses low viscosity inks and resilient flexible printing plates with low pressure applied between the plate cylinder and the substrate. The resilience of the flexographic printing plate combined with low viscosity ink generally makes it possible to print on non-absorbent and rough substrate surfaces that are typically used in packaging.

Printing plates are typically made from rubber or photopolymers. The use of photopolymers for printing plates is becoming more prevalent in the industry. Untreated photopolymers typically consist of elastomers, unsaturated monomers, and UV photo-initiators. They can be soluble in water and/or in organic solvents. A cross-linking reaction can take place as a result of exposure to ultraviolet light. Once cross-linked, the photopolymer is no longer soluble. Photopolymers can be cross-linked locally by partial exposure with the unexposed areas retaining their solubility and therefore their washability.

Photopolymer base plates are available as single or multi-layer plates. Single-layer plates consist of a polyester base or metal backed base, a relief layer of photopolymer, a release layer (also known as slip film), and a protective cover sheet.

The relief layer is an untreated polymer. To process a single-layer plate, the reverse side of the plate is exposed completely and evenly without film copy through a stabilization film. The reverse side exposure brings about the full-surface cross-linking of the lower area of the untreated plate and restricts the wash-off depth. After peeling off the protective cover sheet film from the top surface, the main exposure is done under vacuum through the film negative that has been placed on top. The film negative is in direct contact with a layer on the photopolymer substrate that is known as a slip film membrane. The membrane keeps the film negative from bonding to the photopolymer during the main exposure process. The duration and intensity of the main exposure affects the dot anchoring, the sidewall angle, and the intermediate depths in fine structures such as halftone areas and reverse copy. The main exposure is followed by the washing off process. The unpolymerized areas of the plate are dissolved with a solvent that can also cause the plate to swell. The plate is then dried in order to evaporate any wash-off agent that has penetrated the relief layer and bring the photopolymer back down to the proper gauge. This is followed by a post-exposure without film in order to cross-link all parts of the relief completely as well as a de-tack exposure that removes the tackiness from the surface of the plate.

The term for this process of imaging to a photopolymer plate is known in the printing industry as Computer-to-Plate (CtP). This is defined as a computer image that is electronically transmitted to an output device that applies the image to the surface of a plate. A separate plate is needed for each color to reproduce the artwork designed. To separate the artwork, a RIP (Raster Image Processor) can be used to generate the separations. The RIP then converts the artwork into a language that the output device can receive. The RIP can also control features of the output device such as calibration and alignment.

Untreated plates for direct digital print image transfer by computer to plate systems have a laser energy absorbing layer (black carbon mask) that is revealed on removal of the protective film and which is ablated to produce the image with a beam of a computer-guided laser. In this process, the laser beam ablates the black, energy-absorbent layer, so that dot-by-dot imaging of the plate takes place via laser etching. The black layer takes on the roll of the negative film discussed previously. After imaging, the full surface of the plate is exposed (i.e., first exposure and main exposure) and is processed in the same manner as a single-layer plate in order to create the relief. This process is known in the art as a subtractive process.

Both the film negative process and the ablative or subtractive process described above are time intensive and expensive processes. To this end, there has been a long felt need in the art of flexography for a process that can enable a direct image wise application of a photomask onto a photopolymer substrate in such a manner that high quality flexographic printing plate can be manufactured in a convenient and less expensive way relative to the conventional processes described above.

### SUMMARY OF THE INVENTION

The present invention is directed to a system and method for imaging the surface of a photopolymer plate for use in flexographic printing.

In one aspect of the invention, a method is provided for making a flexographic printing plate. The method includes the steps of providing a photopolymer substrate having a top surface pretreated with a non-gelatinous inkjet receptive coating; image-wise ink jetting an inkjet composition onto a portion of the pretreated surface of the photopolymer substrate to provide a photomask layer, wherein the photomask layer has an optical density of at least about 2.0; exposing the photopolymer substrate to ultraviolet light to cure an unmasked portion of the photopolymer substrate; and processing the photopolymer substrate under conditions effective to render the cured unmasked portion of the photopolymer layer into a raised image surface suitable for use in a flexographic printing process.

In another aspect, the present invention provides a flexographic printing plate produced by the method set forth above.

In still another aspect, the present invention provides a flexographic printing plate precursor. According to this aspect, the flexographic printing plate precursor can comprises a photopolymer layer having a top surface and an opposed bottom surface; and a non-gelatinous inkjet receptive coating layer connected to at least a portion of the photopolymer layer top surface, wherein the non-gelatinous inkjet receptive coating is capable of receiving an inkjetted additive mask having an optical density of at least about 2.0.

In still another aspect, the present invention provides a method for making a flexographic printing plate, comprising the steps of providing a photopolymer substrate having a top surface and an opposed bottom surface; image-wise ink jetting an inkjet composition onto a portion of the top surface of the photopolymer substrate to provide a photomask layer, wherein the photomask layer has an optical density of at least about 2.0; exposing the photopolymer substrate to ultraviolet light to cure an unmasked portion of the photopolymer substrate; and processing the photopolymer substrate under conditions effective to render the cured unmasked portion of the photopolymer layer into a raised image surface suitable for use in a flexographic printing process.

Additional aspects of the invention will be set forth, in part, in the detailed description, figures and any claims which follow, and in part will be derived from the detailed description, or can be learned by practice of the invention. It is to be understood that both the foregoing general description and the following detailed description are exemplary and explanatory only and are not restrictive of the invention as disclosed.

### BRIEF DESCRIPTION OF THE DRAWINGS

The accompanying drawings, which are incorporated in and constitute a part of this specification, illustrate several embodiments of the instant invention and together with the description, serve to explain, without limitation, the principles of the invention.

FIG. 1 illustrates a cross-sectional view of a flexographic printing plate precursor according to one aspect of the present invention.

FIG. 2 illustrates an exploded perspective view of a conventional inkjet print engine.

FIG. 3 illustrates an exploded perspective view of a modified conventional inkjet print engine according to one aspect of the present invention.

FIG. 4 illustrates a perspective view of an inkjet printing device according to one aspect of the present invention.

FIG. 5 illustrates a schematic flow chart diagram of an exemplary conventional subtractive process for imaging a photopolymer plate.

FIG. 6 illustrates a schematic flow chart diagram of an exemplary additive process for imaging photopolymer plates according to one aspect of the present invention.

### DETAILED DESCRIPTION OF THE INVENTION

The present invention can be understood more readily by reference to the following detailed description, and figures, and their previous and following description.

Before the present compositions, devices, and/or methods are disclosed and described, it is to be understood that this invention is not limited to the specific articles, devices, and/or methods disclosed unless otherwise specified, as such can, of course, vary. It is also to be understood that the terminology used herein is for the purpose of describing particular aspects only and is not intended to be limiting.

The following description of the invention is provided as an enabling teaching of the invention in its best, currently known embodiment. Those skilled in the relevant art will recognize that many changes can be made to the embodiments described, while still obtaining the beneficial results of the present invention. It will also be apparent that some of the desired benefits of the present invention can be obtained by selecting some of the features of the present invention without utilizing other features. Accordingly, those who work in the art will recognize that many modifications and adaptations to the present invention are possible and can even be desirable in certain circumstances and are a part of the present invention. Thus, the following description is provided as illustrative of the principles of the present invention and not in limitation thereof, since the scope of the present invention is defined by the claims.

As used herein, the singular forms “a,” “an” and “the” include plural referents unless the context clearly dictates otherwise. Thus, for example, reference to an “hydrophilic polymer” includes aspects having two or more such polymers unless the context clearly indicates otherwise.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

As used herein, a “weight percent” or “percent by weight” of a component, unless specifically stated to the contrary, is based on the total weight of the formulation or composition in which the component is included.

As used herein, the term or phrase “effective,” “effective amount,” or “conditions effective to” refers to such amount or condition that is capable of performing the function or property for which an effective amount is expressed. As will be pointed out below, the exact amount or particular condition required will vary from one embodiment to another, depending on recognized variables such as the materials employed and the processing conditions observed. Thus, it is not always possible to specify an exact “effective amount” or “condition effective to.” However, it should be understood that an appropriate effective amount or effective condition will be readily determined by one of ordinary skill in the art using only routine experimentation.

As used herein, the term “additive process” in one aspect refers to a process that comprises directly depositing a photomask layer onto a substrate in a predetermined pattern. In another aspect, the additive process does not require the removal of any portion of a mask material in order to provide a photomask having a particular or desired pattern.

As used herein, the term “subtractive process” in one aspect refers to a process that comprises removal of mask material in order to provide a photomask layer having a desired pattern.

As used herein, the term “non-gelatinous” in one aspect refers to a material or composition, such as for example an inkjet receptive coating that is at least substantially free of gelatin. In another aspect, as used herein, “non-gelatinous” refers to a material that does not contain any gelatin.

As used herein, the term “photomask” refers to one or more layers of a mask composition having an optical density sufficient to block UV light during exposure in order to prevent the curing of an underlying photopolymer layer.

As used herein, the term “additive mask” refers to a photomask that has been applied to a substrate using an additive process.

As used herein, the term “optical density” is an expression of the electromagnetic transmittance (or absorbance) of a particular material. To this end, the more optically dense that a material is, the slower that an electromagnetic wave will move through the material. As used herein, in one aspect, the optical density of a material is the net value of the transmission optical density (t.o.d.) of the material at 360 nm, obtained by subtracting the t.o.d. of a non-image or non-masked portion from the t.o.d. of an imaged or masked portion.

As used herein, the term “chemically bonding” can include, without limitation, electrostatic bonding, ionic bonding, covalent bonding, and the like. As used herein, a bond, or chemical bond can include, without limitation, a covalent bond, an ionic bond, or an electrostatic bond.

As used herein, the term “hydrophilic polymer” refers to a polymer that has an affinity for water. In another aspect, a hydrophilic polymer is at least substantially soluble in water.

As used herein, the term “hydrophobic polymer” refers to a polymer that in one aspect at least substantially repels or does not combine with water. In one aspect, a hydrophobic polymer is at least substantially incapable of dissolving in water.

As used herein, the term or phrase “comprised primarily of” means a component of a substance or material in an amount that is not less than 50% of the total substance or material by weight.

As used herein, the term “substantially” or “at least substantially” in one aspect refers to at least greater than 80%, at least greater than 85%, at least greater than 90%, at least greater than 95% or even greater than 99% of the stated condition, property, and or effect. For example, an at least substantially dry inkjet receptive coating can in one aspect refer to at least greater than 80% dry, at least greater than 85% dry, at least greater than 90% dry, at least greater than 95% dry or even greater than 99% dry.

As briefly set forth above, in a first aspect, the present invention is directed to a method for making a flexographic printing plate. According to the method, in one aspect an inkjet platform can be used to directly deposit an additive mask layer onto an inkjet receptive coating layer that is pre-applied to the top surface of a photopolymer substrate. The inkjetted additive mask can be applied to a portion of the photopolymer that is not to be exposed and cured during the plate making process. The additive mask can therefore prevent UV light from curing the masked portion of the photopolymer. Any portion of the photopolymer that is not masked can cure during exposure to UV radiation and after subsequent processing can render a raised image surface suitable for use in a flexographic printing process.

The photopolymer substrate can be any conventional photopolymer substrate known in the art of flexographic printing. Typical compositions are photosensitive to UV light having a wavelength in the range from 300 to 420 nm. In one aspect, a conventional photopolymer composition can comprise an elastomer such as a synthetic and/or a natural rubber composition, an unsaturated monomer, and a UV photopolymerization initiator. An exemplary unsaturated monomer compound can in one aspect comprise at least one reactive vinyl group in its molecule. A reactive vinyl group in these compounds can include substituted or unsubstituted vinyl groups having polymerization reactivity, as exemplified by styrene type vinyl groups, acrylic acid type vinyl groups, methacrylic acid type vinyl groups, allyl type vinyl groups, and vinyl ether type vinyl groups, as well as ester vinyl groups as in vinyl acetate.

Examples of a polymerizable compounds satisfying such conditions can include, for example monofunctional monomers such as styrene, methylstyrene, chlorostyrene, bromostyrene, methoxystyrene, dimethylaminostyrene, cyanostyrene, nitrostyrene, hydroxystyrene, aminostyrene, carboxystyrene, acrylic acid, methyl acrylate, ethyl acrylate, cyclohexyl acrylate, acrylamide, methacrylic acid, methyl methacrylate, ethyl methacrylate, propyl methacrylate, butyl methacrylate, phenyl methacrylate, cyclohexyl methacrylate, vinyl pyridine, N-vinylpyrrolidone, N-vinylimidazole, 2-vinylimidazole, N-methyl-2-vinylimidazole, propyl vinyl ether, butyl vinyl ether, isobutyl vinyl ether, beta-chloroethyl vinyl ether, phenyl vinyl ether, p-methylphenyl vinyl ether, and p-chlorophenyl vinyl ether; difunctional monomers such as divinylbenzene, distyryl oxalate, distyryl malonate, distyryl succinate, distyryl glutarate, distyryl adipate, distyryl maleate, distyryl fumarate, distyryl beta,beta′-dimethylglutarate, distyryl 2-bromoglutarate, distyryl alpha,alpha′-dichloroglutarate, distyryl terephthalate, oxalic acid di(ethyl acrylate),oxalic acid di(methyl ethyl acrylate), malonic acid di(ethyl acrylate), malonic acid di(methyl ethyl acrylate), succinic acid di(ethyl acrylate), glutaric acid di(ethyl acrylate), adipic acid di(ethyl acrylate), maleic acid di(diethyl acrylate), fumaric acid di(ethyl acrylate), beta,beta′-dimethylglutaric acid di(ethyl acrylate),ethylenediacrylamide, propylenediacrylamide, 1,4-phenylenediacrylamide, 1,4-phenylenebis(oxyethyl acrylate), 1,4-phenylenebis(oxymethyl ethyl acrylate), 1,4-bis(acryloyloxyethoxy)cyclohexane, 1,4-bis(acryloyloxymethylethoxy) cyclohexane, 1,4-bis(acryloyloxyethoxycarbamoyl) benzene, 1,4-bis(acryloyloxymethy lethoxycarbamoyl)benzene, 1,4-bis (acryloyloxyethoxycarbamoyl)cyclohexane, bis(acryloyloxyethoxycarbamoylcyclohexyl) methane, oxalic acid di(ethyl methacrylate), oxalic acid di(methyl ethyl methacrylate), malonic acid di(ethyl methacrylate), malonic acid di(methyl ethyl methacrylate), succinic acid di(ethyl methacrylate), succinic acid di(methyl ethyl methacrylate), glutaric acid di(ethyl methacrylate), adipic acid di(ethyl methacrylate), maleic acid di(ethyl methacrylate), fumaric acid di(ethyl methacrylate), fumaric acid di(methyl ethyl methacrylate), beta,beta′-dimethylglutaric acid di(ethyl methacrylate), 1,4-phenylenebis(oxyethyl methacrylate), and 1,4-bis(methacryloyloxyethoxy)cyclohexane, acryloyloxyethoxyethyl vinyl ether; trifunctional monomers such as pentaerythritol triacrylate, pentaerythritol trimethacrylate, pentaerythritol tri(hydroxystyrene), cyanuric acid triacrylate, cyarnuric acid trimethacrylate, 1,1,1-trimethylolpropane triacrylate, 1,1,1-trimethylolpropane trimethacrylate, cyanuric acid tri(ethyl acrylate), 1,1,1-trimethylolpropane tri(ethylacrylate), dipentaerythritol hexaacrylate, cyanuric acid tri(ethyl vinyl ether), a condensate of a reaction product between 1,1,1-trimethylolpropane and three-fold moles of toluenediisocyanate, with hydroxyethyl acrylate, and a condensate of a reaction product pattern 1,1,1-trimethylolpropane and three-fold moles of hexanediisocyanate, with p-hydroxystyrene; and tetrafunctional monomers such as ethylenetetraacrylamide, and pylenetetraacrylamide. Two or more of these polymerizable polymer precursors can be used in combination.

The photopolymerization initiator used in a photopolymer substrate of the present invention can include, for example, carbonyl compounds, sulfur compounds, halogen compounds, photopolymerization initiators of redox type, and peroxide initiators sensitized with dye such as pyrilium. Specifically, the carbonyl compounds include diketones as exemplified by phenyl, 4,4′-dimethoxybenzyl, diacetyl, and camphorquinone; benzophenones as exemplified by 4,4′-bis(diethylamino) benzophenone, and 4,4′-dimethoxylbenzophenone; acetophenones as exemplified by acetophenone, and 4-methoxyacetophenone; benzoin alkyl ethers; thioxanthones as exemplified by 2-chlorothioxanthone, 2,4-dichlorothixanthone, 2,4-diethylthioxanthone, and thioxanthone-3-carboxylic acid-beta-methoxy ethyl ester; chalcones and styrylketones having a dialkylamino group; and cumarins as exemplified by 3,3′-carbonylbis(7-methoxycumarin), and 3,3′-carbonylbis (7-diethylaminocumarin). The sulfur compounds include disulfides as exemplified by dibenzothiazolyl sulfide, and decylphenyl sulfide. The halogen compounds include, for example, carbon tetrabromide, quinolinesulfonyl chloride, and S-triazines having a trihalomethyl group. The photopolymerization initiators of the redox type include those used in combination of a trivalent iron compound (as exemplified by ferric ammonium citrate) with a peroxide, and those used in combination of a photoreducing coloring matter such as riboflavin or Methylene Blue with a reducing agent such as triethanolamine or ascorbic acid.

In the photopolymerization initiator described above, two or more photopolymerization initiators can also be used in combination to effect a more efficient photopolymerization reaction. Such combination of the photopolymerization initiators includes a combination of styryl ketones or chalcones having a dialkylamino group or cumarins, with S-triazines having a trihalomethyl group or camphorquinone.

The photopolymer substrate composition can optionally contain additional ingredients such as a binder or film-forming agent, a solid solvent, a surfactant, an anti-static agent, a plasticiser to improve the flexibility of the material, a stabiliser to prevent monomers from premature crosslinking during storage, and a dye to permit easy inspection of the plate so that correct exposure and registration can be determined.

The binder or film-forming agent usable in the photopolymer layer can include, for example, cellulose esters, such as nitrocellulose, cellulose phosphate, cellulose sulfate, cellulose acetate, cellulose propionate, cellulose butyrate, cellulose myrystate, cellulose palmitate, cellulose acetate propionate, and cellulose acetate butyrate; cellulose ethers, such as methyl cellulose, ethyl cellulose, propyl cellulose, and butyl cellulose; vinyl resins, such as polystyrene, polyvinyl chloride, polyvinyl acetate, polyvinyl butyral, polyvinyl acetal, polyvinyl alcohol, and polyvinyl pyrrolidone; copolymer resins, such as a styrene/butadiene copolymer, a styrene/acrylonitrile copolymer, a styrene/butadiene/acrylonitrile copolymer, and a vinyl chloride/vinyl acetate copolymer; acrylic resins, such as polymethyl methacrylate, polymethyl acrylate, polybutyl acrylate, polyacrylic acid, polymethacrylic acid, polyacrylamide, and polyacrylonitrile; polyesters, such as polyethylene terephthalate; polyarylate resins, such as poly(4,4′-isopropylidene, diphenylene-co-1,4-cyclohexylenedimethylene carbonate), poly(ethylenedioxy-3,3,-phenylene thiocarbonate), poly(4,4′-isopropylidene, diphenylene carbonate-co-terephthalate), poly(4,4′-isopropylidene,diphenylene carbonate), poly(4,4′-sec-butylidene,diphenylene carbonate), and poly(4,4′-isopropylidene,diphenylene carbonate-blockoxyethylene); plyamides; polyimides; epoxy resins; phenolic resins; polyolefins, such as polyethylene, polypropylene, and chlorinated polyethylene; and natural polymers.

In an exemplary and non-limiting aspect, a specific photopolymer substrate composition which can be used in the photopolymer substrate of the present invention comprises an elastomer such as a rubber chosen for its specific hardness, e.g. polyisoprene, a monomer which undergoes radical-induced photopolymerisation, e.g. butanedioldiacrylate, and a photoinitiator such as benzildimethylketal which upon light absorption during a UV flood exposure process can produce radicals that can trigger a polymerisation reaction. Specific commercially available photopolymer substrates that can be used in accordance with the present invention, include without limitation, the Cyrel photopolymer substrate available from Dupont, the Nyloflex photopolymer substrate available from BASF, and the Flexolight photopolymer substrate available from MacDermid.

The photopolymer substrate according to the present invention can optionally comprise a base layer connected to the bottom surface of the photopolymer layer. In one aspect, the base layer can comprise a dimensionally stable foil which is transparent in the wavelength range used for obtaining the so-called floor of the flexographic printing plate by back-exposure of the photopolymer layer. In one aspect, the base layer can comprise plastic resin, such as cellulose nitrate film, cellulose acetate film, polyvinylacetal film, polystyrene film, polyethylene terephthalate film, polycarbonate film, polyvinylchloride film or poly-.alpha.-olefin films such as polyethylene or polypropylene film. In another aspect, the thickness of such organic resin film can be between 5 and 35 um. In another aspect, the backing or base layer can comprise a metal sheet or metal-coated substrate. Typical examples are aluminum, steel or copper sheets. The base can be mechanically and/or chemically pre-treated or provided with an adhesive layer in order to ensure good adhesion to the photopolymer layer. Such an adhesive layer can consist, for example, of the conventional single- or two-component adhesives, e.g. those based on polyurethane. In still another aspect, the base layer can further carry an antihalation layer below the photopolymer layer.

According to another aspect, the photopolymer substrate can further comprise a release layer also known as a slip film membrane, deposited on a surface of the photopolymer substrate. As one of skill in the art will appreciate, a conventional film negative process can utilize the release layer in order to prevent a negative from sticking to the photopolymer substrate that can be caused by pressure and heat during the main exposure. As such, in one aspect, the methods of the present invention are suitable for use on photopolymer substrates that also comprise such release or slip film membranes.

The inkjet receptive coating in one aspect is a hydrophilic coating characterized by having a relatively high affinity for aqueous based inkjet ink compositions and is capable of facilitating the product of relatively high quality inkjet printed images. In another aspect, the inkjet receptive coating is capable of facilitating relatively fast drying of an aqueous ink composition as described herein. In still another aspect, the inkjet receptive coating is capable of chemically bonding with an aqueous based ink composition and thus can prevent ultraviolet light from curing the portion of the photopolymer substrate masked by an aqueous based ink photomask layer.

The inkjet receptive coating can in one aspect comprise any hydrophilic polymer having receptive affinity for an aqueous inkjet composition as described herein. In one aspect, the inkjet receptive coating can comprise a nitrogen containing polymer, such as, and without limitation, polyvinyl pyrrolidone, polyacrylamide, acrylamide/acrylic acid, poly(2-acrylamido-2-methyl propane sulphonic acid), poly(diethylene triamine-co-adipic acid), polyvinyl pyridine, polyvinyl imidazole, polyimidazoline quaternized, polyethylene imine, polyethylene imine epichlorohydrine modified, polyethylene imine ethoxylated, poly(N,N,-dimethyl-3,5-dimethylene piperidinium chloride, polyurethane, melamin resins, urea resins, nitrile rubbers, or albumin.

In another aspect, the inkjet receptive coating can comprise a non-nitrogen containing polymer, such as, and without limitation, cellulose derivatives such as carboxymethyl cellulose, hydroxyethyl cellulose, hydroxypropyl cellulose, hydroxypropyl methyl cellulose, starch, dextran, polyvinyl alcohol, polyvinyl alcohol derivatives such as acetoacetylated derivatives, polyvinyl acetate, polyvinyl acetal, polyalkyleneoxides, latices such as copoly(styrene-butadiene), carboxylated polymers or polyacrylates.

In an alternative aspect, the inkjet receptive coating can comprise a hydrophobic polymer. To this end, in one aspect, the hydrophobic polymer can have an affinity for a solvent based inkjet composition. For example, suitable hydrophobic include, without limitation, polystyrene, polymethylmethacrylate (PMMA), polyolefins (e.g. polyethylene (PE), polypropylene (PP)), polyvinylchloride (PVC), silicones, and block copolymers containing one or more of these constituents.

The inkjet receptive coating can further comprise an organic or inorganic filler and/or porous particulate material. Inorganic materials can include e.g. synthetic silica, talc, clay, koalin, diatomaceous earth, calcium carbonate, magnesium carbonate, aluminum hydroxide, aluminum oxide, boehmite and pseudo-boehmite, titanium oxide, zinc oxide, barium sulfate, calcium sulfate, zinc sulfide, satin white, aluminum silicate, calcium silicate, lithopone, etc. Organic materials can include e.g. polystyrene, polymethacrylate, polymethylmethacrylate, elastomers, ethylene-vinylacetate copolymers, polyesters, polyester-copolymers, polyacrylates polyvinylethers, polyamides, polyolefines, polysilicones, guanamine resins, polytetrafluoroethylenes, elastomeric styrene-butadiene rubber (SBR), elastomeric butadiene-acrylonitrile rubber, urea resins or urea-formalin resins.

Further optional components of the inkjet receptive coating of the present invention are so-called mordanting agents which by fixing the colorant of the jetted ink composition strongly improve the water-fastness of the finished image. Such mordants can in one aspect be (co)polymers containing cationic functions such as quaternary ammonium groups, fosfonium, sulfonium, and guadinium groups as disclosed in U.S. Pat. No. 4,371,582, U.S. Pat. No. 4,575,465, U.S. Pat. No. 4,649,064, GB 2210071, EP 423829, DE 3109931, U.S. Pat. No. 4,585,724, EP 295338, EP 306564, U.S. Pat. No. 5,314,747, EP 609930, WO 94/20304, WO 94/20305, WO 94/20306, EP 615853, EP 615884, and EP 618214. Also inorganic mordants can be used such as those that are disclosed and described e.g. in U.S. Pat. No. 5,560,996, EP 704316 and EP 754560.

In still another aspect, the inkjet receptive coating of the present invention can comprises a plasticizer such as ethylene glycol, dietylene glycol, propylene glycol, polyethylene glycol, glycerol monomethylether, glycerol monochlorohydrin, ethylene carbonate, propylene carbonate, tetrachlorophthalic anhydride, tetrabromophthalicanhydride, urea phosphate, triphenylphosphate, glycerolmonostearate, propylene glycol monostearate, tetramethylene sulfone, N-methyl-2-pyrrolidone, N-vinyl-2-pyrrolidone, and polymer latices with low Tg value such as polyethylacrylate or polymethylacrylate.

One or more surfactants can be incorporated in the inkjet receptive coating of the present invention. The surfactant can be cationic, anionic, amphoteric, and/or nonionic. Non-limiting examples of suitable optional surfactants are N-alkylamino acid salts, alkylether carboxylic acid salts, acylated peptides, alkylsulfonic acid salts, alkylbenzene and alkylnaphthalene sulfonic acid salts, sulfosuccinic acid salts, olefin sulfonic acid salts, N-acylsulfonic acid salts, sulfonated oils, alkylsulfonic acid salts, alkylether sulfonic acid salts, alkylallylethersulfonic acid salts, alkylamidesulfonic acid salts, alkylphosphoric acid salts, alkyletherphosphoric acid salts, alkylallyletherphosphoric acid salts, alkyl and alkylallylpolyoxyethylene ethers, alkylallylformaldehyde condensed acid salts, blocked polymers having polyoxypropylene, polyoxyethylene polyoxypropylalkylethers, polyoxyethyleneether of glycolesters, polyoxyethyleneether of sorbitanesters, polyoxyethyleneether of sorbitolesters, polyethyleneglycol aliphatic acid esters, glycerol esters, sorbitane esters, propyleneglycol esters, sugaresters, fluoro C₂-C₁₀ alkylcarboxylic acids, disodium N-perfluorooctanesulfonyl glutamate, sodium 3-(fluoro-C₆-C₁₁-alkyloxy)-1-C₃-C₄ alkyl sulfonates, N-[3-(perfluorooctanesulfonamide)-propyl]-N,N-dimethyl-N-carboxymethylene ammonium betaine, fluoro-C₁₁-C₂₀ alkylcarboxylic acids, perfluoro C₇-C₁₃ alkyl carboxylic acids, perfluorooctane sulfonic acid diethanolamide, Li, K and Na perfluoro C₄-C₁₂ alkyl sulfonates, N-propyl-N-(2-hydroxyethyl)perfluorooctane sulfonamide, perfluoro C₆-C₁₀ alkylsulfonamide propyl sulfonylglycinates, bis-(N-perfluorooctylsulfonyl-N-ethanolaminoethyl)phosphonate, mono-perfluoro C₆-C₁₆ alkyl-ethyl phosphonates, and perfluoroalkylbetaine.

The inkjet receptive coating can further comprise a “spacing agent” which is used here as equivalent to “matting agent” or “roughening agent”. Said spacing agent can in one aspect preferably be hydrophilic. Useful examples are the different types of silica such as that disclosed e.g. in U.S. Pat. No. 3,084,131, U.S. Pat. No. 4,892,591, U.S. Pat. No. 4,902,568, EP 379964, EP 423829, U.S. Pat. No. 5,165,973, EP 739747, EP 781666, EP 803374, EP 862510, WO 97/20691; starch or modified starch particles such as disclosed in EP 445327, EP 480362, EP 524635; and the alkali-soluble beads of U.S. Pat. No. 4,906,560 and EP 0 584 407.

As one of ordinary skill in the art will appreciate, flexographic printing is commonly used in connection with printing and labeling of packing materials for use in connection with perishable and/or consumable items, such as for example, food or medicines. Therefore, in another aspect, it will be appreciated by one of skill in the art that the inkjet receptive coating of the instant invention is substantially free of natural polymers that can increase the likelihood of bacterial formation. For example, in one aspect, the inkjet receptive coating is substantially free of proteins. In another exemplary aspect, the inkjet receptive coating is substantially free of gelatin.

As mentioned above, the inkjet receptive coating according to the present invention can be pre-applied to a surface of a photopolymer subtracted as described herein. To this end, in one aspect, the method of the present invention can further comprise the steps of first providing an untreated photopolymer substrate an then applying a liquid inkjet receptive coating composition to the top surface of the photopolymer substrate. The applied liquid inkjet receptive coating composition can then be dried using a conventional drying technique. In one aspect, the liquid inkjet receptive coating composition can be dried under ambient conditions. In another aspect, the liquid inkjet receptive coating composition can be dried using conventional oven drying techniques. As set forth above, the photopolymer substrate can further comprise an option slip film membrane applied to the surface thereof. As such, it will be appreciated that the inkjet receptive coating can in one aspect be applied to a photopolymer substrate having a slip film membrane, or, in an alternative aspect, the inkjet receptive coating can be applied directly to the photopolymer layer itself.

The inkjet receptive coating can be applied using any conventional means for applying a coating composition to a substrate. For example, and without limitation, the inkjet receptive coating can be applied using a high volume, low-pressure (HVLP) spraying unit, a short nap paint roller, a foam brush, or even a foam roller and/or a metering rod either hand held or by a form of an applicator. Further, the inkjet receptive coating can be applied in a layer having any desired thickness. For example, the inkjet receptive coating, when applied in its liquid form can have a thickness in the range of from 5 to 200 microns. The inkjet receptive coating in its dry form can measure a film thickness in the range of from 0.5 to 50 microns. In one aspect, the thickness of the ink receptive coating in liquid form is approximately 3.8 mils or 97.4 microns. In another aspect, the thickness of the inkjet receptive coating in its dry form can be approximately 5-6 microns.

As set forth above, the inkjet receptive coating can comprise a hydrophobic and/or a hydrophilic polymer. Thus, in one aspect, the inkjet receptive coating in liquid form can comprise water. Accordingly, in an exemplary and non-limiting aspect, the liquid inkjet receptive coating can comprise at least 50 weight percent water. In another aspect, the liquid inkjet receptive coating can comprise at least 55 weight percent water, at least 60 weight percent water, at least 65 weight percent water, at least 70 weight percent water, at least 75 weight percent water, at least 80 weight percent water, or even at least 85 weight percent water. In still another aspect, the liquid inkjet receptive coating can comprise at least 90 weight percent water. In a specific and exemplary aspect, the liquid inkjet receptive coating composition is a non-gelatinous aqueous based composition comprising polyvinyl alcohol, such as the Clear Glossy Inkjet Receptive Coating, product number C-123-26, commercially available from Ontario Specialty Coatings, Inc.

In an alternative aspect, the ink receptive coating in liquid form can comprise a solvent. In one aspect, the solvent used can include a single solvent or a mixture of two or more solvents in any ratio. In one aspect, the solvent can be selected based upon the solubility of the polymer to be used. For example, the solvent can be a mixture of solvents, one of which will solubilize the polymer and the other that does not.

In one aspect, the solvent includes organic solvents such as, for example, hydrocarbons, halogenated hydrocarbons, ethers, esters, acids, bases, alcohols, ketones, alkanes, aromatics, and the like. In another aspect, the solvent is methylene chloride, chloroform, acetone, anisole, ethyl acetate, methyl acetate, N-methyl-2-pyrrolidone, hexafluoroisopropanol, tetrahydrofuran, dimethylsulfoxide, water, 2-pyrollidone, triethyl citrate, ethyl lactate, propylene carbonate, benzyl alcohol, benzyl benzoate, Miglyol 810, isopropanol, ethanol, super critical carbon dioxide, acetonitrile, water, or a mixture thereof.

In an exemplary and non-limiting aspect, the liquid inkjet receptive coating can comprise at least 50 weight percent solvent. In another aspect, the liquid inkjet receptive coating can comprise at least 55 weight percent solvent, at least 60 weight percent solvent, at least 65 weight percent solvent, at least 70 weight percent solvent, at least 75 weight percent solvent, at least 80 weight percent solvent, or even at least 85 weight percent solvent. In still another aspect, the liquid inkjet receptive coating can comprise at least 90 weight percent solvent.

Once the liquid inkjet receptive coating is at least substantially dried, the inkjet receptive coating can in an exemplary aspect comprise at least 50 weight percent of a hydrophilic polymer and/or hydrophobic polymer as described above. In another aspect, the at least substantially dried inkjet receptive coating can comprise at least 55 weight percent of a hydrophilic polymer and/or hydrophobic polymer, at least 60 weight percent of a hydrophilic polymer and/or hydrophobic polymer, at least 65 weight percent of a hydrophilic polymer and/or hydrophobic polymer, at least 70 weight percent of a hydrophilic polymer and/or hydrophobic polymer, at least 75 weight percent of a hydrophilic polymer and/or hydrophobic polymer, at least 80 weight percent of a hydrophilic polymer and/or hydrophobic polymer, or even at least 90 weight percent of a hydrophilic polymer and/or hydrophobic polymer.

If desired, the inkjet receptive coating can be covered by a removable protective film or layer that can be removed prior to inkjet application of an inkjet composition onto the inkjet receptive coating. In one aspect, the protective film or layer can be a peelable foil. In one aspect, the foil can comprise a plastic resin such as, for example, such as cellulose nitrate film, cellulose acetate film, polyvinylacetal film, polystyrene film, polyethylene terephthalate film, polycarbonate film, polyvinylchloride film or poly-.alpha.-olefin films such as polyethylene or polypropylene film.

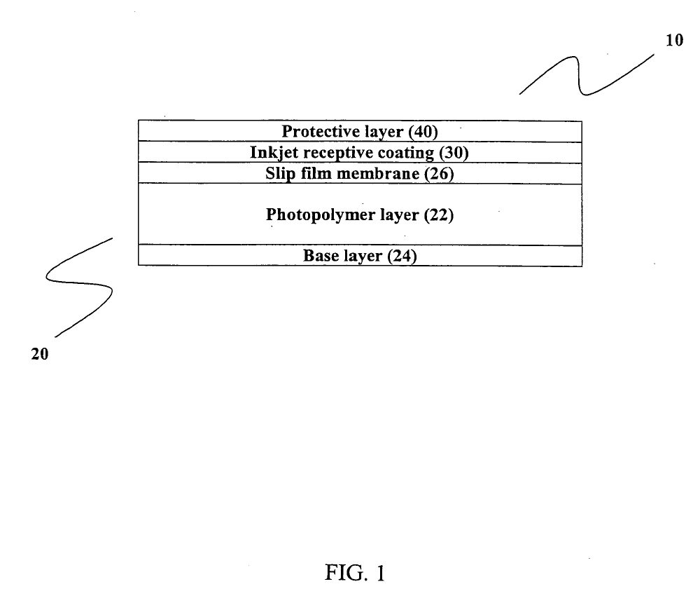

With specific reference to FIG. 1, an exemplary flexographic printing plate precursor 10 according to one aspect of the present invention is illustrated. The exemplary flexographic printing plate precursor 10 comprises a photopolymer substrate 20. The substrate 20 is comprised of a photopolymer layer 22, optional base layer 24, and optional slip film or release membrane 26. Deposited on the optional slip film layer 26 is an inkjet receptive coating 30. Further, an optional removable protective layer 40 is deposited on the inkjet receptive coating layer 30.

The inkjet composition according to the present invention can be any inkjet composition that is capable of providing a mask density required to block UV light during exposure in order to prevent the curing of masked photopolymer layer. In one aspect, the inkjet composition is compatible with an inkjet receptive coating as described above. In another aspect, the inkjet composition is directly compatible with a surface of a photopolymer substrate in the absence of a inkjet receptive coating as described herein.

It will be appreciated by one of ordinary skill in the art that a suitable inkjet composition can be optimized or adjusted such that the spectral absorption of the ink composition corresponds to the particular wavelength or range of wavelengths of light used during the exposure of the photopolymer to UV light. To this end, suitable inkjet compositions can comprise an aqueous based and/or solvent based vehicle system. Suitable solvents can include polar and/or non-polar solvents, including without limitation, those solvents previously set forth above as suitable for use in the inkjet receptive coating. The inkjet compositions can also comprise a pigment based and/or dye based colorant system. Additionally, the inkjet composition of the instant invention can also comprise optional additives such as glycols, detergents, thickeners, polymeric binders, preservatives, humectants, surfactants, biocides, buffering agents, chelating agents and defoaming agents.

Water-based inks can in one aspect typically contain about 75-90 weight % of water. In order to avoid dry tipping on the orifice of the printing head, they can contain a so-called humectant or mixtures of humectants which can comprise (poly)alcohols. Suitable humectants include glycols such as diethyleneglycol, glycerine and polyethyleneglycol, N-methyl-pyrrolidone, 2-pyrrolidone, N-methyl-2-pyrrolidone, isopropanol, and 1,2-dimethyl-2-imidazolidone. Certain humectants such as N-methyl-pyrrolidone and 2-pyrrolidone have been found to improve the solubility of the colorant in the ink and thus can also serve the dual role as humectant and as co-solvent. Typically these humectants are present in a concentration ranging from 5 to 15%.

The colorant in the inkjet composition of the present invention is preferably a black colorant system. In one aspect, the ink composition comprises a black dye colorant system. To this end, an exemplary and commercially available ink composition suitable for use in the instant invention is the Graphic Dye Black Ink, available from American Imaging Systems.

In another aspect, the inkjet composition can comprise a pigment based colorant system. For example, the colorant can comprise a carbon black pigment. In one aspect, the pigment concentration can be at least 2% by weight. In another aspect, the pigment concentration can be about 5% by weight. Multiple types of inks containing carbon black pigment are commercially available. They include carbon blacks such as Regal 400R, Mogul L, Elftex 320 from Cabot Co., or Carbon Black FWI8, Special Black 250, Special Black 350, Special Black 550, Printex 25, Printex 35, Printex 55, Printex 150T from Degussa Co., and Pigment Black 7.

As one of skill in the art will appreciate, pigment particles should be sufficiently small to permit free flow of the ink through the ink-jet printing device, especially at the ejecting nozzles of the print head that usually have a diameter ranging from less than 10 microns to 50 microns. The pigment particle size also has an influence on the pigment dispersion stability, which is critical throughout the life of the ink. It is also desirable to use small particles for maximum color strength. Accordingly, the average particle diameter of pigment particles can in one aspect be from about 0.005 μm to about 15 μm. Preferably, the pigment particle size can range from about 0.005 to about 5 μm, and more preferably from about 0.005 to about 1 μm, and most preferably from about 0.005 to about 0.3 μm. Pigment particle sizes outside these ranges can, of course, be used as long as the objectives of the present invention are achieved.

In still another aspect, if the colorant system is not in itself sufficiently absorptive in the UV spectral region it a UV absorbing additive, such as for example a UV absorptive dye, can be added to the ink composition. Suitable UV absorbers are disclosed e.g. in EP 0 252 550, U.S. Pat. No. 4,311,787, U.S. Pat. No. 4,082,554, U.S. Pat. No. 4,053,315, EP 0 519 306, EP 0524593, EP 0 524 594, EP 0 529 737, JP-A 03-38636, JP-A 03-13936, JP-A 03-41442, DE 4142935, EP 0 552 010, JP-A 03-48234, U.S. Pat. No. 5,155,015, EP 0 525 445, WO 93/5443, JP-A 03-78741, WO 93/13458, U.S. Pat. No. 4,923,788, EP 0 411 819, JP-A 61-205934, JP-A 01-259358, JP-A 02-73343, JP-A 02-71261 and EP 0 495 406. Additionally, it will also be appreciated that the use of an added UV absorber can reduce the necessary pigment loading in a pigment based inkjet composition and can in one aspect also provide the benefit of minimizing the potential for sedimentation and clogging of the inkjet print heads.

The optical density of the additive mask can, in one aspect, be adjusted or optimized to provide a desired mask density sufficient to block UV light during exposure and to thereby prevent the curing of a masked photopolymer layer. To this end, in one aspect, the additive mask of the instant invention can have an optical density of at least 2.0. In another aspect, the optical density can be in the range of from at least 2.0 to approximately 7.0. In still another aspect, the optical density of the mask can be in the range of from approximately 3.5 to 6.0. As such, the desired optical density can, in one aspect, also be controlled and optimized by depositing a single mask layer or, alternatively, a plurality of mask layers. Accordingly, it will be appreciated that by altering the number of mask layers applied to the inkjet receptive coating, a desired optical density can be achieved.

The inkjet platform or printing device suitable for depositing the inkjet composition on to an inkjet receptive coating can be any conventional inkjet platform capable of imaging a photopolymer substrate. For example, in one aspect, the inkjet platform is capable of imaging a substrate having a thickness in the range of from about 0.001 to about 0.500 inches, including without limitation, specific thicknesses of about 0.005, 0.010, 0.050, 0.100, 0.150, 0.200, 0.250, 0.300, 0.350, 0.400 and 0.450. In another aspect, the inkjet platform is capable of imaging a substrate having a thickness in the range of from about 0.003 to about 0.275 inches. Exemplary and non-limiting inkjet printing devices that can be used to perform the methods of the present invention include the HP890C ink-jet printer (available from Hewlett-Packard) and the NovaJet 880 (available from Encad, Inc.).

Alternatively, in another aspect of the present invention, modifications can be made to conventional inkjet platforms that are not otherwise capable of imaging substrates having a thickness in the range set for the above. To this end, in an exemplary aspect, a commercially available conventional inkjet platform engine such as the Epson 7600, Epson 9600, and Epson 4000 (all available from Seiko Epson) and the Mimaki JV4 inkjet printer (available from Mimaki) can be modified in order to have the ability to image virtually any desired substrate thickness.

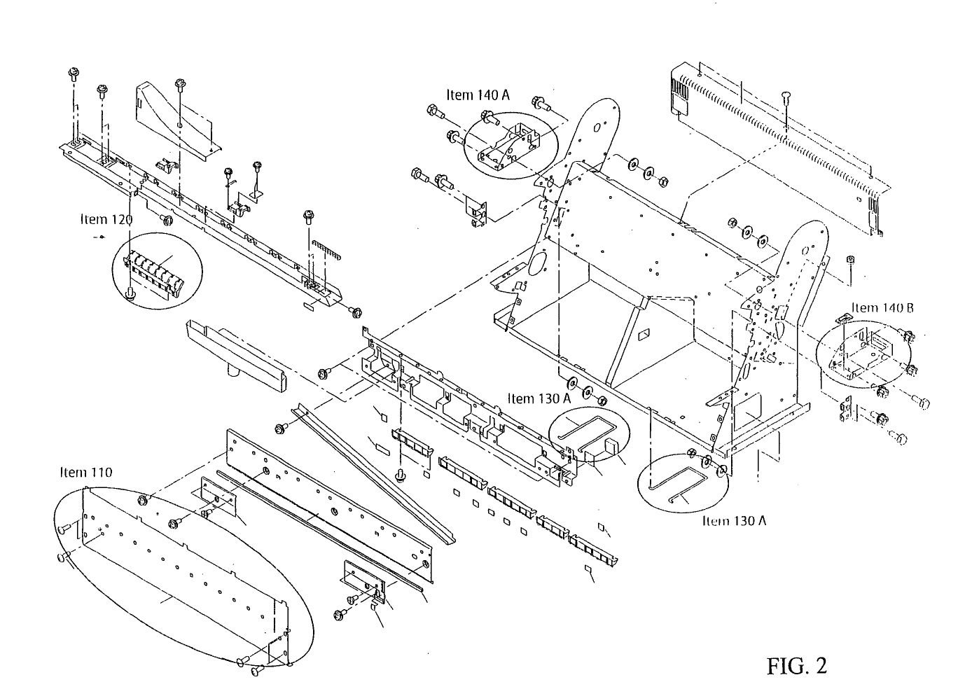

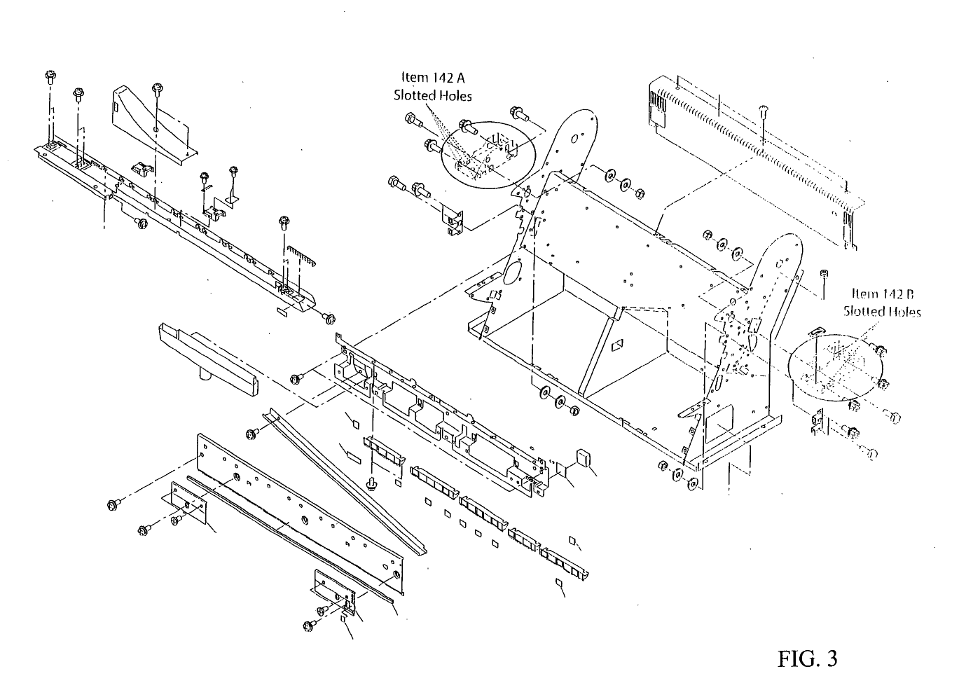

For example, an exemplary modification of an Epson 7600 or Epson 9600 is depicted by a comparison of FIG. 2 and FIG. 3. FIG. 2 illustrates an exploded perspective view of a commercially available Epson 7600/9600 inkjet engine 100. Among the several component parts illustrated therein, the engine comprises an exit tray 110, a paper guide 120, paper guides 130(a) and 130(b) and carriage brackets 140(a) and 140(b). In contrast, a modified Epson 7600 or Epson 9600 inkjet engine that is capable of imaging a substrate having a thickness in the range of from about 0.001 to about 0.275 inches is depicted in FIG. 3. As illustrated, the modification comprises the removal of exit tray 110, the removal of paper guide 120, and the removal of paper guides 130(a) and 130(b). In addition, the modification further comprises the incorporation of slotted holes 142(a) and 142(b) into the carriage brackets 140(a) and 140(b) respectively.

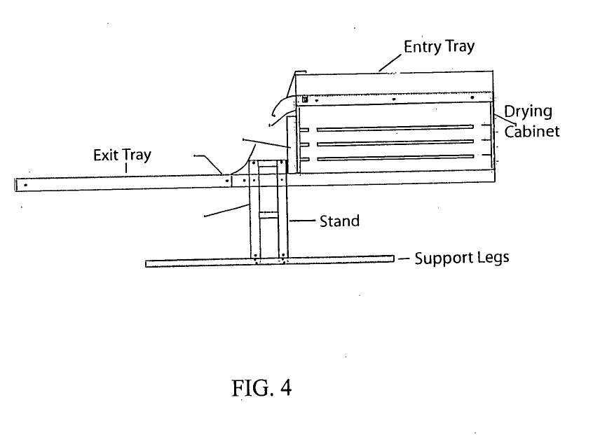

Further, FIG. 4 illustrates a side view of an exemplary and non-limiting inkjet printing assembly 200, that can be constructed and arranged to house a modified conventional inkjet printing device as described above. As illustrated, the inkjet assembly 200 comprises a base member comprised of a stand 210 and support legs 220. The assembly further comprises a drying cabinet or housing 230, a substrate entry tray 240 and a substrate exit or receiving tray 250.

Exposure to UV radiation can first comprise exposing the back or bottom surface of the photopolymer substrate, i.e., a base layer, to UV light. This can harden or cure the “floor” and establish a maximum relief depth during subsequent processing or development. A subsequent exposure of the face or top surface of the photopolymer substrate to UV light through a masked area can harden or cure the areas or portions of the photopolymer substrate that have not been masked. In one aspect, it will be appreciated that the parameters and profile of the UV exposure can be adjusted or optimized to provide a desired tonal reproduction. For example, the amount of intensity of the UV lamps as well as the amount of time exposed can affect the amount of cross-linking that occurs from the surface of the plate. Additionally, it is not uncommon for there to be temperature differences between different areas of the exposure unit. Thus, in a non-temperature controlled system, the outer areas can be cooler than a central area of the unit. Further, depending on the number of hours that the exposure unit operates, the intensity of the fluorescent lamps can differ even within a single UV lamp. Thus, heat build up within the exposure unit can result in changes in cross-linking characteristics. As one of skill in the art will appreciate, any one or more of these factors can be controlled and or optimized in order to provide a desired accuracy within a printing plate and such control or optimization parameter will be readily known or otherwise obtained through routine experimentation.

After the exposure to UV light, the photopolymer substrate can be processed under conditions effective to render the cured unmasked portion of the photopolymer layer into a raised image surface suitable for use in a flexographic printing process.

This processing step can, in one aspect, first comprise the removal of the photomask layer. In one aspect, the photomask can be removed using water. In another aspect, the water can be heated to a temperature in the range of from approximately 50-100° F. degrees. In still another aspect, the water can be heated to a temperature of about 70° F.

Once the photomask layer has been removed, the uncured portion of the photopolymer substrate can then be processed or developed using any known or conventional processing for developing a photopolymer substrate, including without limitation, an aqueous washout process, a solvent based washout process, and/or a thermal developing process. In an exemplary aspect, percholorethylene alternative solvents (PAS) can be used as a plate wash. PAS's can be used to develop almost any solvent washable photopolymer plate. PASs typically have a flashpoint of 150-200° F. and are stable under normal room temperature and storage conditions. Further, the solvent can be recycled for multiple uses but its useable lifetime can depend on the number and size of the plates and the amount of material to be removed.

As one of skill in the art will appreciate upon review of the foregoing detailed description, in one aspect, the present invention provides an additive masking process that differs significantly from the conventional subtractive processes known in the art today. To this end, conventional methods start with a photopolymer plate that is pre-coated with a solid mask. This mask can be a carbon coating that is laminated to the surface of the photopolymer plate. The plate can then mounted to a cylinder and placed in a machine that rotates the cylinder at a high speed. A machine equipped with a laser electronically ablates or etches away the carbon to reveal the polymer to be exposed and cured by UV light. This is known as a subtractive process in so far as a portion of a deposited mask layer is being removed in order to provide a desired mask layer.

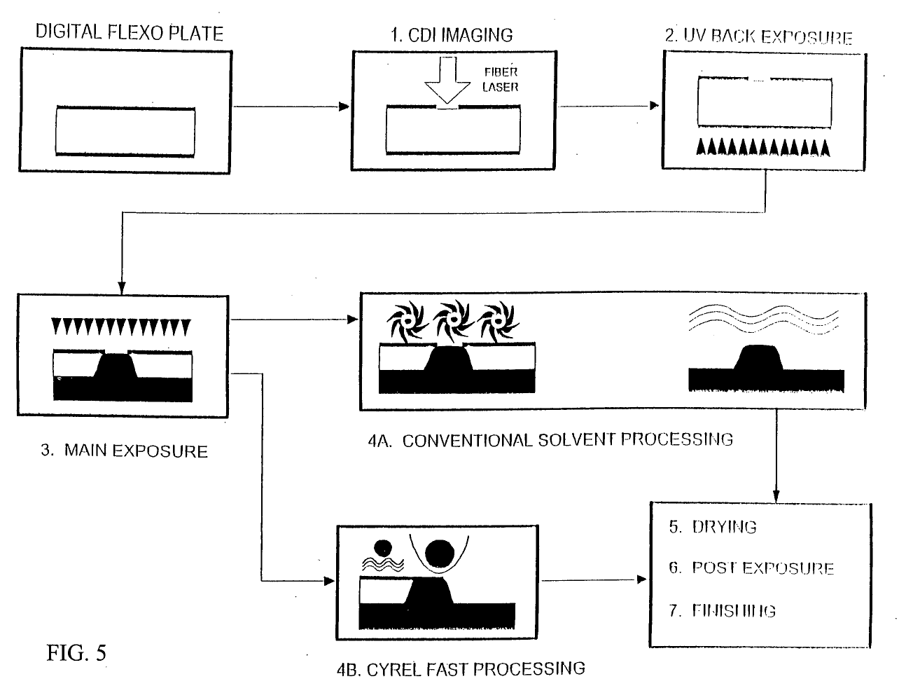

FIG. 5 illustrates a flow chart diagram of a conventional subtractive process as described above. As depicted, a digital flexographic plate is a photopolymer substrate that is coated with a thin layer of carbon mask compound. In step 1, a laser writes data from a graphics file into the black carbon layer. This process is called laser ablation because the imaging is achieved by thermally burning away the carbon compound. In step 2, the back side of the digital plate is exposed to ultraviolet light to bring about the full-surface cross-linking of the lower area of the plate and to restrict the wash-off depth. The digital plate is then exposed to ultraviolet light to produce the image in the plate as shown in step 3. In step 4B, the Cyrel Fast system can be applied to produce the plate. This step avoids the washing process completely. Alternatively, conventional solvent processing can occur as shown in step 4A. The final steps are drying (step 5), post exposure (step 6) and finishing (step 7).

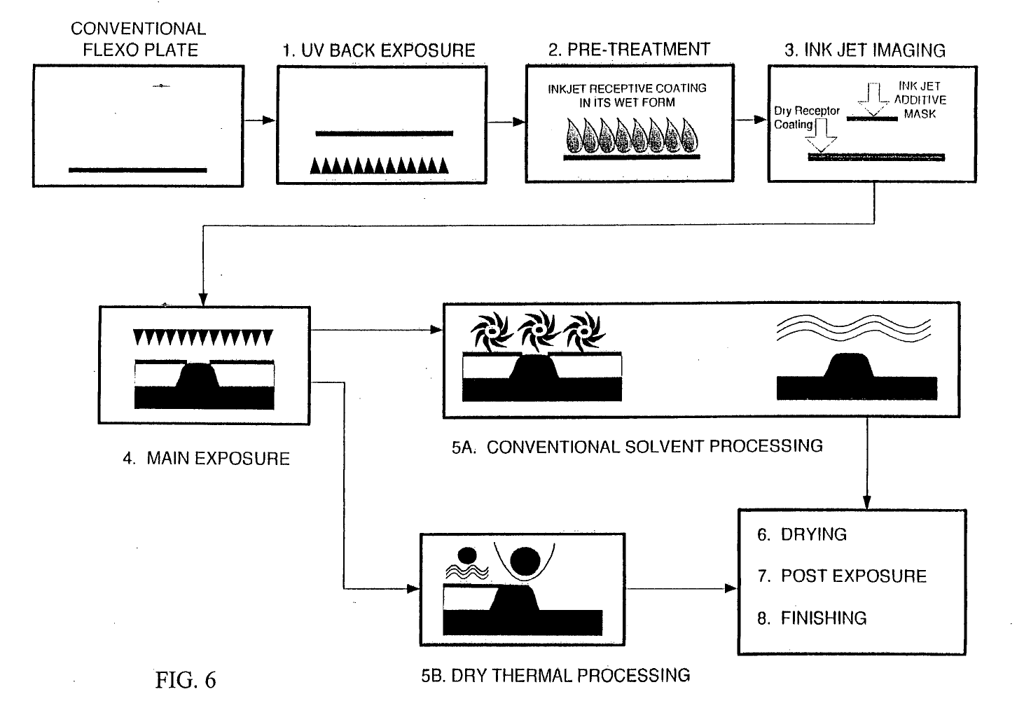

In contrast to the conventional subtractive method depicted in FIG. 5 and described above, FIG. 6 illustrates a flow diagram of an exemplary additive process according to the present invention. As depicted, in step 1 of the inventive process, a reverse side exposure of a conventional photopolymer plate to ultraviolet light results in a cross-linking of the lower area of the untreated plate and restricts wash-off depth. In step 2, an inkjet receptive coating in a liquid wet form is applied to the upper surface of the photopolymer plate. The upper surface of the untreated plate can include a slip film membrane, in which case, the receptive coating would be applied to the slip film membrane. The inkjet receptive coating in an exemplary embodiment comprises at least 90% water by weight. The dry receptive coating shown in step 3 comprises at least 50% polyvinyl alcohol. An inkjet additive mask is applied to a portion of the coated photopolymer plate in step 3. The additive mask is formed by a black imaging ink, the optical density of which can be controlled by the number of layers that are applied. In step 4, the main exposure to ultraviolet light occurs. The additive mask applied in step 3 prevents the main exposure from curing the masked portion or region of the photopolymer plate. In step 5A, conventional water processing occurs to wash away the additive mask. Alternatively, in step 5B, dry thermal processing is performed. The final steps are drying to evaporate any solvent that has penetrated the photopolymer layer (step 6), post exposure to cross-link all parts of the plate (step 7), and finishing of the flexographic plate (step 8).

Throughout this application various publications are referenced. It should be understood that the disclosures of these publications in their entireties are hereby incorporated by reference into this application for all purposes.

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for making a flexographic printing plate, comprising the steps of:
(a) providing a photopolymer substrate having a top surface pretreated with a non-gelatinous inkjet receptive coating;
(b) image-wise ink jetting an inkjet composition onto a portion of the pretreated surface of the photopolymer substrate to provide a photomask layer, wherein the photomask layer has an optical density of at least about 2.0;
(c) exposing the photopolymer substrate to ultraviolet light to cure an unmasked portion of the photopolymer substrate; and
(d) processing the photopolymer substrate under conditions effective to render the cured unmasked portion of the photopolymer layer into a raised image surface suitable for use in a flexographic printing process.

2. The method of claim 1, wherein the inkjet receptive coating comprises a hydrophilic polymer.

3. The method of claim 1, wherein the inkjet receptive coating comprises a nitrogen containing polymer selected from polyvinyl pyrrolidone, polyacrylamide, acrylamide/acrylic acid, poly(2-acrylamido-2-methyl propane sulphonic acid), poly(diethylene triamine-co-adipic acid), polyvinyl pyridine, polyvinyl imidazole, polyimidazoline quaternized, polyethylene imine, polyethylene imine epichlorohydrine modified, polyethylene imine ethoxylated, poly(N,N,-dimethyl-3,5-dimethylene piperidinium chloride, polyurethane, melamin resin, urea resin, nitrile rubber, and albumin.

4. The method of claim 1, wherein the inkjet receptive coating comprises a non-nitrogen containing polymer selected from carboxymethyl cellulose, hydroxyethyl cellulose, hydroxypropyl cellulose, hydroxypropyl methyl cellulose, starch, dextran, polyvinyl alcohol, polyvinyl acetate, polyvinyl acetal, polyalkyleneoxide, copoly(styrene-butadiene), a carboxylated polymer, and polyacrylate.

5. The method of claim 1, wherein the inkjet receptive coating comprises polyvinyl alcohol.

6. The method of claim 1, wherein the inkjet receptive coating comprises a hydrophobic polymer.

7. The method of claim 1, wherein the inkjet receptive coating is at least substantially protein free.

8. The method of claim 1, wherein step (a) comprises the steps of: (i) providing a photopolymer substrate; (ii) applying a non-gelatinous liquid inkjet receptive coating composition to the top surface of the photopolymer substrate; and (iii) drying the non-gelatinous liquid inkjet coating composition.

9. The method of claim 8, wherein the liquid inkjet receptive coating composition is comprised primarily of water.

10. The method of claim 9, wherein the liquid inkjet receptive coating composition comprises at least 90 weight percent water.

11. The method of claim 8, wherein the liquid inkjet receptive coating composition is comprised primarily of solvent.

12. The method of claim 1, wherein the inkjet receptive coating is capable of chemically bonding with the photomask layer to prevent ultraviolet light from curing the portion of the photopolymer substrate masked by the photomask layer.

13. The method of claim 1, wherein the photomask layer is an additive inkjet mask.

14. The method of claim 1, wherein the photomask layer is a solvent based black ink composition that can bond to the inkjet receptive coating.

15. The method of claim 1, wherein the photomask layer is an aqueous black ink composition that can bond to the inkjet receptive coating.

16. The method of claim 15, wherein an optical density of the photomask layer is controlled by applying the ink in a plurality of layers.

17. The method of claim 1, wherein the photomask layer has an optical density in the range from about 3.5 to about 6.0.

18. The method of claim 1, further comprising the step of exposing a bottom surface of the photopolymer substrate to ultraviolet light prior to step (c).

19. The method of claim 1, wherein the photopolymer substrate further comprises a slip film membrane positioned between the photopolymer substrate and the inkjet receptive coating.

20. The method of claim 1, further comprising removing the photomask layer with a wash after step (c).

21. The method of claim 1, wherein the step of exposing the photopolymer substrate comprises advancing the photopolymer substrate incrementally in a flat method during an imaging process.

22. The method of claim 1, wherein the photopolymer substrate has a thickness in the range of from about 0.003 inches to about 0.275 inches.

23. A flexographic printing plate produced by the method of claim 1.

24. A flexographic printing plate precursor, comprising:
a photopolymer layer having a top surface and an opposed bottom surface; and
a non-gelatinous inkjet receptive coating layer connected to at least a portion of the photopolymer layer top surface, wherein the non-gelatinous inkjet receptive coating is capable of receiving an inkjetted additive mask layer having an optical density of at least about 2.0.

25. The flexographic printing plate precursor of claim 24, further comprising a base layer connected to the photopolymer layer bottom surface.

26. The flexographic printing plate precursor of claim 24, further comprising a slip film membrane interposed between the photopolymer layer top surface and the inkjet receptive coating.

27. The flexographic printing plate precursor of claim 24, wherein the inkjet receptive coating comprises a hydrophilic polymer.

28. The flexographic printing plate precursor of claim 24, wherein the inkjet receptive coating comprises a nitrogen containing polymer selected from polyvinyl pyrrolidone, polyacrylamide, acrylamide/acrylic acid, poly(2-acrylamido-2-methyl propane sulphonic acid), poly(diethylene triamine-co-adipic acid), polyvinyl pyridine, polyvinyl imidazole, polyimidazoline quaternized, polyethylene imine, polyethylene imine epichlorohydrine modified, polyethylene imine ethoxylated, poly(N,N,-dimethyl-3,5-dimethylene piperidinium chloride, polyurethane, melamin resin, urea resin, nitrile rubber, and albumin.

29. The flexographic printing plate precursor of claim 24, wherein the inkjet receptive coating comprises a non-nitrogen containing polymer selected from carboxymethyl cellulose, hydroxyethyl cellulose, hydroxypropyl cellulose, hydroxypropyl methyl cellulose, starch, dextran, polyvinyl alcohol, polyvinyl acetate, polyvinyl acetal, polyalkyleneoxide, copoly(styrene-butadiene), a carboxylated polymer, and polyacrylate.

30. The flexographic printing plate precursor of claim 24, wherein the inkjet receptive coating comprises polyvinyl alcohol.

31. The flexographic printing plate precursor of claim 30, wherein the inkjet receptive coating comprises at least 50 weight percent polyvinyl alcohol.

32. The flexographic printing plate precursor of claim 24, wherein the inkjet receptive coating is at least substantially protein free.

33. The flexographic printing plate precursor of claim 24, wherein the inkjetted additive mask layer comprises an aqueous black ink composition that can bond to the non-gelatinous inkjet receptive coating.

34. The flexographic printing plate precursor of claim 24, further comprising an inkjetted additive mask layer having an optical density of at least about 2.0.

35. The flexographic printing plate precursor of claim 34, wherein the inkjetted additive mask has an optical density in the range from about 3.5 to about 6.0.

36. The flexographic printing plate precursor of claim 24, further comprising a removable protective layer connected to at least a portion of the non-gelatinous inkjet receptive coating layer.

37. A method for making a flexographic printing plate, comprising the steps of:
a) providing a photopolymer substrate having a top surface and an opposed bottom surface;
b) image-wise ink jetting composition onto a portion of the top surface of the photopolymer substrate to provide a photomask layer, wherein the photomask layer has an optical density of at least about 2.0;
c) exposing the photopolymer substrate to ultraviolet light to cure an unmasked portion of the photopolymer substrate; and
d) processing the photopolymer substrate under conditions effective to render the cured unmasked portion of the photopolymer layer into a raised image surface suitable for use in a flexographic printing process.
